(19) United States
(12) Patent Application Publication
(10) Pub. No.: US 2024/0311524 A1
(43) Pub. Date: Sep. 19, 2024

(54) SYSTEM AND METHOD FOR IDENTIFYING CONTACT FEATURES OF B-REP-BASED COMPUTER AIDED DESIGN MODELS

(71) Applicant: HCL Technologies Limited, New Delhi (IN)

(72) Inventors: Budi Bharath Kumar, Pune (IN); Hari Krishnan Elumalai, Chennai (IN); Akash Agrawal, Pune (IN); Pankaj Panda, Navi Mumbai (IN)

(21) Appl. No.: 18/225,707

(22) Filed: Jul. 25, 2023

(30) Foreign Application Priority Data
Mar. 14, 2023 (IN) 202311016853

(51) Int. Cl. G06F 30/17

(52) U.S. Cl. CPC G06F 30/17

(57) ABSTRACT

The invention relates to method and system for identifying contact features of Boundary Representation (B-Rep)-based Computer Aided Design (CAD) models. The method includes determining body type associated with body from body types based on information extracted from boundary representation of body; identifying associated body pairs from valid bodies based on proximity between each two of valid bodies and predefined threshold proximity; for each of associated body pairs, identifying face pairs for each body of associated body pairs based on single-body criteria, and for each pair of associated body pairs based on multi-body criteria; and identifying contact features and corresponding contact parameters from each of face pairs based on plurality of user control parameters.

### TECHNICAL FIELD

Generally, the invention relates to Boundary Representation (B-Rep) models. More specifically, the invention relates to a system and method for identifying contact features of Boundary Representation (B-Rep)-based Computer Aided Design (CAD) models.

### BACKGROUND

Typically, a Boundary representation (B-Rep) Computer Aided Design (CAD) model of a mechanical part includes faces, edges, and vertices. The faces, the edges, and the vertices may be connected to form a topological structure of the mechanical part. Information of the B-Rep model of the mechanical part may be stored in a graph structure. In the graph structure, each node represents a face, and each link/connection represents an edge. This type of representation helps in evaluating properties of the mechanical part. The properties may include mass, volume, moment of inertia, and the like. Additionally, such B-Rep models enable computer-based analysis of stress and strains in the mechanical part under different loading conditions. Further, a B-Rep model may also be cut and examined in a manner like an actual part. Therefore, the B-Rep model of the mechanical part is known as a solid model.

Today, various software based on solid modeling are widely used by engineers to create models of the mechanical parts that are intended to eventually be manufactured. Examples of the software may include SolidWorks® and Catia® (Dassault Systems®), Creo Parametric® (PTC®), and the like.

A B-Rep-based CAD model (referred as a body) of mechanical parts may include one or more bodies. If two bodies are touching or in proximity of a specified tolerance value, then the relationship between the two bodies is said to be in contact. Also, in case of a single body, if different regions are touching or in proximity of a specified tolerance value, then the relationship between those regions is said to be in contact. Analysis of such contact features is essential in industries, for example, to determine a type of joining method (such as welding, brazing, etc.) to be used to achieve the final product corresponding to the bodies. Such analysis helps in estimating the time and cost required in production. Additionally, when the contact features are known, the production process can also be automated.

The conventional techniques fail to address such analysis of the contact features between solid models. The present invention is directed to overcome one or more limitations associated with the known arts.

### SUMMARY

In one embodiment, a method for identifying contact features of Boundary Representation (B-Rep)-based Computer Aided Design (CAD) models is disclosed. The method may include, for each body of a plurality of bodies, determining a body type associated with the body from a plurality of body types based on information extracted from a boundary representation of the body. Each of the plurality of bodies may be a B-Rep-based CAD model, and each of the plurality of body types may be one of an invalid body type and a valid body type. The method may further include identifying one or more associated body pairs from a set of valid bodies based on a proximity between each two of the set of valid bodies and a predefined threshold proximity. The body type of each of the set of valid bodies may be the valid body type. The method may further include, for each of the one or more associated body pairs, identifying one or more face pairs for each body of the one or more associated body pairs based on a single-body criteria, and for each pair of the one or more associated body pairs based on a multi-body criteria. The method may further include identifying a set of contact features and corresponding contact parameters from each of the one or more face pairs based on a plurality of user control parameters.

In another embodiment, a system for identifying contact features of B-Rep-based CAD models is disclosed. The system may include a processor and a memory communicatively coupled to the processor. The memory may store processor-executable instructions, which on execution, may further cause the processor to, for each body of a plurality of bodies, determine a body type associated with the body from a plurality of body types based on information extracted from a boundary representation of the body. Each of the plurality of bodies may be a B-Rep-based CAD model, and each of the plurality of body types may be one of an invalid body type and a valid body type. The processor-executable instructions, on execution, may further cause the processor to identify one or more associated body pairs from a set of valid bodies based on a proximity between each two of the set of valid bodies and a predefined threshold proximity. The body type of each of the set of valid bodies may be the valid body type. The processor-executable instructions, on execution, may further cause the processor to, for each of the one or more associated body pairs, identify one or more face pairs for each body of the one or more associated body pairs based on a single-body criteria, and for each pair of the one or more associated body pairs based on a multi-body criteria. The processor-executable instructions, on execution, may further cause the processor to identify a set of contact features and corresponding contact parameters from each of the one or more face pairs based on a plurality of user control parameters.

In yet another embodiment, a non-transitory computer-readable medium storing computer-executable instructions for identifying contact features of B-Rep-based CAD models is disclosed. The stored instructions, when executed by a processor, may cause the processor to perform operations including, for each body of a plurality of bodies, determining a body type associated with the body from a plurality of body types based on information extracted from a boundary representation of the body. Each of the plurality of bodies may be a B-Rep-based CAD model, and each of the plurality of body types may be one of an invalid body type and a valid body type. The operations may further include identifying one or more associated body pairs from a set of valid bodies based on a proximity between each two of the set of valid bodies and a predefined threshold proximity. The body type of each of the set of valid bodies may be the valid body type The operations may further include, for each of the one or more associated body pairs, identifying one or more face pairs for each body of the one or more associated body pairs based on a single-body criteria, and for each pair of the one or more associated body pairs based on a multi-body criteria. The operations may further include identifying a set of contact features and corresponding contact parameters from each of the one or more face pairs based on a plurality of user control parameters.

It is to be understood that both the foregoing general description and the following detailed description are exemplary and explanatory only and are not restrictive of the invention, as claimed.

### BRIEF DESCRIPTION OF THE DRAWINGS

The present application can be best understood by reference to the following description taken in conjunction with the accompanying drawing figures, in which like parts may be referred to by like numerals

FIG. 1 illustrates a block diagram of a system for identifying contact features of Boundary Representation (B-Rep)-based Computer Aided Design (CAD) models, in accordance with some embodiments of the present disclosure.

FIG. 2 illustrates a flow diagram of an exemplary process for identifying contact features of Boundary Representation (B-Rep)-based Computer Aided Design (CAD) models, in accordance with some embodiments of the present disclosure.

FIGS. 3A and 3B illustrate exemplary contact scenarios for one or more bodies, in accordance with some embodiments of the present disclosure.

FIGS. 4A-4F illustrate exemplary contact types for bodies, in accordance with some embodiments of the present disclosure.

FIGS. 5A-5C illustrate exemplary contact regions for different contact types of bodies, in accordance with some embodiments of the present disclosure.

FIGS. 6A-6B illustrate exemplary scenarios while identifying associated body pairs, in accordance with some embodiments of the present disclosure.

FIG. 7 is a block diagram of an exemplary computer system for implementing embodiments consistent with the present disclosure.

### DETAILED DESCRIPTION OF THE DRAWINGS

The following description is presented to enable a person of ordinary skill in the art to make and use the invention and is provided in the context of particular applications and their requirements. Various modifications to the embodiments will be readily apparent to those skilled in the art, and the generic principles defined herein may be applied to other embodiments and applications without departing from the spirit and scope of the invention. Moreover, in the following description, numerous details are set forth for the purpose of explanation. However, one of ordinary skill in the art will realize that the invention might be practiced without the use of these specific details. In other instances, well-known structures and devices are shown in block diagram form in order not to obscure the description of the invention with unnecessary detail. Thus, the present invention is not intended to be limited to the embodiments shown, but is to be accorded the widest scope consistent with the principles and features disclosed herein.

While the invention is described in terms of particular examples and illustrative figures, those of ordinary skill in the art will recognize that the invention is not limited to the examples or figures described. Those skilled in the art will recognize that the operations of the various embodiments may be implemented using hardware, software, firmware, or combinations thereof, as appropriate. For example, some processes can be carried out using processors or other digital circuitry under the control of software, firmware, or hard-wired logic. (The term “logic” herein refers to fixed hardware, programmable logic and/or an appropriate combination thereof, as would be recognized by one skilled in the art to carry out the recited functions). Software and firmware can be stored on computer-readable storage media. Some other processes can be implemented using analog circuitry, as is well known to one of ordinary skill in the art. Additionally, memory or other storage, as well as communication components, may be employed in embodiments of the invention.

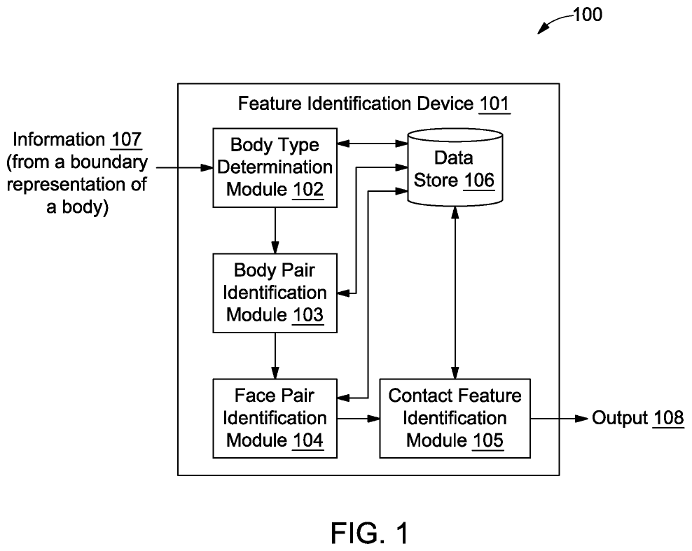

Referring now to FIG. 1, a system 100 for identifying contact features of Boundary Representation (B-Rep)-based Computer Aided Design (CAD) models is illustrated, in accordance with some embodiments of the present disclosure. The system 100 automatically identifies the contact features of the CAD models by determining contact types, contact entities, and contact regions. The recognized contact features may be utilized in various fields, for example, for selecting the most suitable welding method based on the contact type, for determining welding time and cost, in automation of welding path, and the like.

To identify the contact features, the system 100 may include a feature identification device 101. The feature identification device 101 may perform various operations, for which the feature identification device 101 may further include a body-type determination module 102, a body-pair identification module 103, a face-pair identification module 104, and a contact feature identification module 105. Further, the feature identification device 101 may also include a data store 106 to store data and intermediate results generated by the modules 102-105.

The body-type determination module 102 may be configured to receive information 107 extracted from a boundary representation of a body. In some embodiment, the information may be stored in the data store 106 from where the body-type determination module 102 may extract the information upon requirement. Further, in some embodiments, the body-type determination module 102 may be configured to determine a body type associated with the body from a plurality of body types based on the information. This may be performed for each body of a plurality of bodies. It should be noted that each of the plurality of bodies may be a B-Rep-based CAD model. Also, it should be noted that each of the plurality of body types may be one of an invalid body type and a valid body type. The invalid body type may include a non-manifold body type, a multi-part body type, a surface body type, or a wire body type. Further, the body-type determination module 102 may be communicatively coupled to the body-pair identification module 103 to transmit valid bodies. Also, the body-type determination module 102 may be communicatively coupled to the data store 106 to transmit information about the determined body types (i.e., a set of valid bodies and a set of invalid bodies).

The body-pair identification module 103 may be configured to identify one or more associated body pairs from the set of valid bodies based on a proximity between each two of the set of valid bodies and a predefined threshold proximity. The body type of each of the set of valid bodies may be the valid body type. In particular, to identify the one or more body-pairs, the set of valid bodies may be received by the body-pair identification module 103 from the body-type determination module 102 or extracted from the data store 106. Further, the body-pair identification module 103 may calculate the proximity between boundary envelopes of the two bodies, for each two bodies of the set of valid bodies. Further, in an embodiment, the body-pair identification module 103 may establish the two bodies as an associated body pair when the proximity is within the predefined threshold proximity. In an alternative embodiment, the body-pair identification module 103 may establish the two bodies as a non-contacting body pair when the proximity is not within the predefined threshold proximity. The body-pair identification module 103 may be operatively coupled to the face-pair identification module 104 and the data store 106.

In one embodiment, the face-pair identification module 104 may be configured to identify one or more face pairs for each body of the one or more associated body pairs based on a single-body criteria. To identify the one or more face pairs based on the single-body criteria, if the proximity between two faces of the body is within the predefined threshold proximity may be determined, for each body of each of the one or more associated body pairs. In another embodiment, the face-pair identification module 104 may be configured to identify one or more face pairs for each pair of the one or more associated body pairs based on a multi-body criteria. To identify the one or more face pairs based on the multi-body criteria, if the proximity between a face of each of the body pair is within the predefined threshold proximity may be determined, for each body pair of the one or more associated body pairs. The face-pair identification module 104 may be communicatively coupled to the contact feature identification module 105 and the data store 106.

The contact feature identification module 105 may be configured to identify a set of contact features from each of the one or more face pairs, which may be rendered as an output 108 to a user. It should be noted that a plurality of user control parameters may be considered to identify the set of contact features. The set of contact features may include contact parameters. The contact parameters may include one or more contact types, one or more contact entities, and one or more contact regions. Further, it should be noted that the one or more contact types may be at least one of a face-face contact type, a face-vertex contact type, a face-edge contact type, an edge-edge contact type, an edge-vertex contact type, and a vertex-vertex contact type. Also, it should be noted that the one or more contact regions may include a two-dimensional (2D) contact region, a one-dimensional (1D) contact region, and a zero-dimensional (0D) contact region.

The feature identification device 101 may also include a validation module (not shown in FIG. 1) to validate each of the one or more contact types based on the corresponding one or more contact regions. It should be noted that the face-face contact type may correspond to the 2D contact region. Further, each of the face-edge contact type and the edge-edge contact type may correspond to the 1D contact region. And, each of the face-vertex contact type, the edge-vertex contact type, and the vertex-vertex contact type corresponds to the 0D contact region.

It should be noted that the system 100 and associated feature identification device 101 may be implemented in programmable hardware devices such as programmable gate arrays, programmable array logic, programmable logic devices, or the like. Alternatively, the system 100 and the feature identification device 101 may be implemented in software for execution by various types of processors. An identified engine/module of executable code may, for instance, include one or more physical or logical blocks of computer instructions which may, for instance, be organized as a component, module, procedure, function, or other construct. Nevertheless, the executables of an identified engine/module need not be physically located together but may include disparate instructions stored in different locations which, when joined logically together, comprise the identified engine/module and achieve the stated purpose of the identified engine/module. Indeed, an engine or a module of executable code may be a single instruction, or many instructions, and may even be distributed over several different code segments, among different applications, and across several memory devices.

As will be appreciated by one skilled in the art, a variety of processes may be employed for identifying the contact features of the B-Rep-based CAD models. For example, the exemplary system 100 and associated feature identification device 101 may identify the contact features of the B-Rep-based CAD models, by the process discussed herein. In particular, as will be appreciated by those of ordinary skill in the art, control logic and/or automated routines for performing the techniques and steps described herein may be implemented by the system 100 and feature identification device 101 either by hardware, software, or combinations of hardware and software. For example, suitable code may be accessed and executed by the one or more processors on the feature identification device 101 to perform some or all of the techniques described herein. Similarly, application specific integrated circuits (ASICs) configured to perform some or all the processes described herein may be included in the one or more processors on the system 100 and associated feature identification device 101.

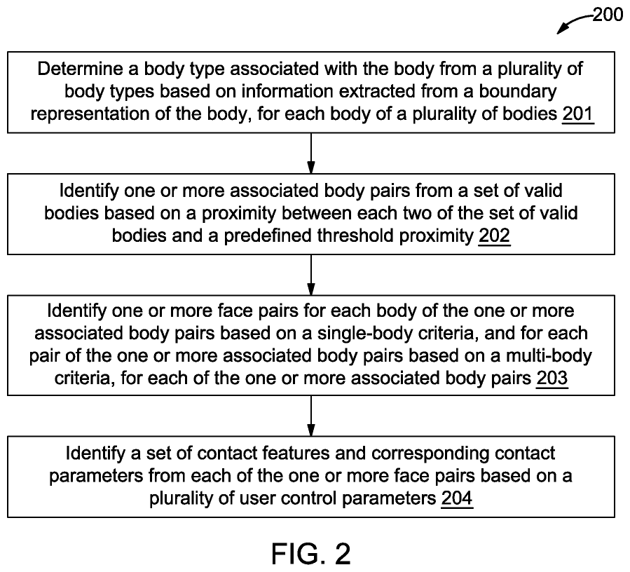

Referring now to FIG. 2, an exemplary process 200 for identifying the contact features of the B-Rep based CAD models is depicted via a flow diagram, in accordance with some embodiments of the present disclosure. Each step of the process 200 may be performed by the feature identification device 101. FIG. 2 is explained in conjunction with FIG. 1.

At step 201, a body type associated with the body from a plurality of body types may be determined through the body-type determination module 102. This step may be performed for each body of a plurality of bodies. It should be noted that information (for example the information 107) extracted from a boundary representation of the body may be used to determine the body type. Further, each of the plurality of bodies may be a B-Rep-based CAD model and each of the plurality of body types may be one of an invalid body type and a valid body type. It should be noted that the invalid body type may be one of a non-manifold body type, a multi-part body type, a surface body type, or a wire body type.

In other words, an input including B-rep based CAD models corresponding to the plurality of bodies may be received. Further, each body may be checked if it defines a valid body. Standard checks for a B-rep based CAD model may be applied to check validity of the body data structure. Bodies failing the check may be referred to as invalid bodies and ignored for contact feature identification.

A body that is not manufactured by a conventional process may be considered as a non-manifold body, and standard checks provided by commercially available Solid Modeling software may be applied to determine this category of the body. Further, a body that includes disconnected volumetric regions may be considered as a multi-part body. A body that includes a single face or a connected set of faces that do not enclose a volume, may be considered as a surface body. It may be noted that a wire body includes a single edge or a connected set of edges that may not enclose an area. Predefined algorithms may be used to detect disconnected volumetric regions in the body, the surface body, and the wire body.

At step 202, one or more associated body pairs may be identified from a set of valid bodies based on a proximity between each two of the set of valid bodies and a predefined threshold proximity. This step may be performed through the body-pair identification module 103. The body type of each of the set of valid bodies is the valid body type. In some embodiments, the set of valid bodies may be received from the body type determination module 102. Further, the proximity between boundary envelopes of the two bodies may be calculated for each two bodies of the set of valid bodies. Thereafter, the two bodies may be established as an associated body pair when the proximity is within the predefined threshold proximity, or a non-contacting body pair when the proximity is not within the predefined threshold proximity.

In other words, a body and its associated body may be identified using boundary envelopes of the bodies. If the boundary envelopes of these two bodies are touching or overlapping, and the proximity between the bodies is within the predefined threshold proximity, then a pair of these bodies may be considered as an associated body pair for finding the contacts between them.

At step 203, one or more face pairs may be identified for each of the one or more associated body pairs through the face-pair identification module 104. The one or more face pairs may be identified for each body of the one or more associated body pairs based on a single-body criteria and for each pair of the one or more associated body pairs based on a multi-body criteria. Further, in some embodiments, if the proximity between two faces of the body is within the predefined threshold proximity may be determined for each body of each of the one or more associated body pairs, for identifying the one or more face pairs based on the single-body criteria. Additionally, in some embodiments, if the proximity between a face of each of the body pair is within the predefined threshold proximity may be determined for each body pair of the one or more associated body pairs, to identify the one or more face pairs based on the multi-body criteria.

In other words, associated body pairs may be processed through to the face-pair identification module 104. Each body in the associated body pair may be processed first to find face-pairs for single body contact scenario, and then to find face-pairs for multibody contact scenario. Criteria for identifying the face pairs for the single body contact scenario is that the bounding envelope of faces of a body should be touching or overlapping and proximity between the faces should be within the predefined threshold proximity. It should be noted that adjacent faces may not be considered while finding the face pairs

Moreover, a criteria for identifying the face pairs for the multi-body contact scenario is that the bounding envelope of a face of one body within an associated body pair should be touching or overlapping a face of another body within the associated body pair and the proximity between the faces should be within the predefined threshold proximity.

Thereafter, at step 204, a set of contact features including contact parameters may be identified through the contact feature identification module 105. The contact features may be identified from each of the one or more face pairs and based on a plurality of user control parameters. The contact parameters may include one or more contact types, one or more contact entities, and one or more contact regions. The user control parameters may include the predefined threshold proximity and contact types. By way of an example, the predefined threshold proximity may be set by the user and may modified when required. By way of another example, the user may provide inputs on types of contacts. The user control parameters may include the predefined threshold proximity and contact types. By way of an example, the predefined threshold proximity may be set by the user and may be modified when required. By way of another example, the user may provide inputs on types of contacts.

Further, the one or more contact types may include at least one of a face-face contact type, a face-vertex contact type, a face-edge contact type, an edge-edge contact type, an edge-vertex contact type, and a vertex-vertex contact type. The one or more contact regions may include a 2D contact region, a 1D contact region, and a 0D contact region.

In other words, the face pairs identified in both scenarios may be processed further to the contact feature identification module 105, to find the contact type in the face pairs based on user provided contact types. For example, for the face-face contact type, one face should overlap the second face. For the face-edge contact type, one face should overlap any of edges of the second face or vice versa. For the face-vertex contacts type, any of vertices of the first face should lie inside the second or vice versa. For the edge-edge contact type, edges of the first face should overlap edges of the second face or vice versa. For the edge-vertex contacts type, any of vertices of the first Face should lie between end points of edges of the second face or vice versa. For the vertex-vertex contact type, any of vertices of the first face should lie on any of vertices of the second face.

Thereafter, in some embodiments, each of the one or more contact types may be validated based on the corresponding one or more contact regions. It should be noted that the face-face contact type may correspond to the 2D contact region. Each of the face-edge contact type and the edge-edge contact type may correspond to the 1D contact region. Each of the face-vertex contact type, the edge-vertex contact type, and the vertex-vertex contact type may correspond to the 0D contact region.

For example, contact region should be the valid 2-D contact region with some area, for validation of the face-face contact type. The contact region should be a valid 1-D contact region, for the face-edge contact type and the edge-edge contact type. Further, for example, the contact region should be a valid 0-D contact region, for the edge-vertex contact type, the vertex-vertex contact type, and the face-vertex contact type.

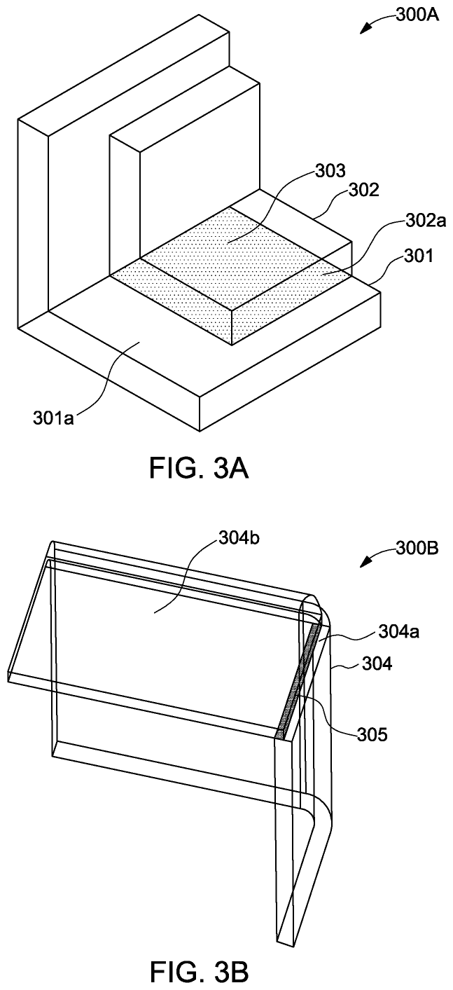

Referring now to FIGS. 3A-3B, contact scenarios for one or more bodies are illustrated, in accordance with some embodiments of the present disclosure. FIGS. 3A-3B are explained in conjunction with FIGS. 1-2. In FIG. 3A, a multibody-contact scenario 300A is illustrated. The multi-body contact scenario 300A includes a first body 301 and a second body 302. Further, the first body 301 and the second body 302 are in contact through their faces 301a and 302a, respectively. A region between bodies (i.e., the face 301a of the first body 301 and the face 302a of the second body 302) may define contact in the multi-body scenario 300A. For example, a face-face contact region 303 is represented as the contact between the first body 301 and the second body 302.

FIG. 3B illustrates a single-body scenario 300B. The single body scenario 300B includes a body 304. A region between two faces 304a and 304b of the body 304 defines a contact, in case of the single body scenario 300B. For example, a face-face contact region 305 is represented as the contact between the faces 304a and 304b of the body 304.

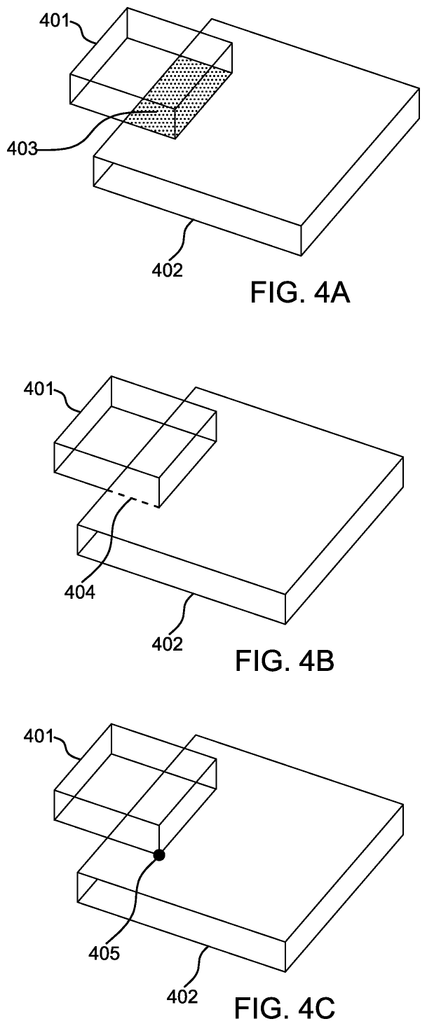

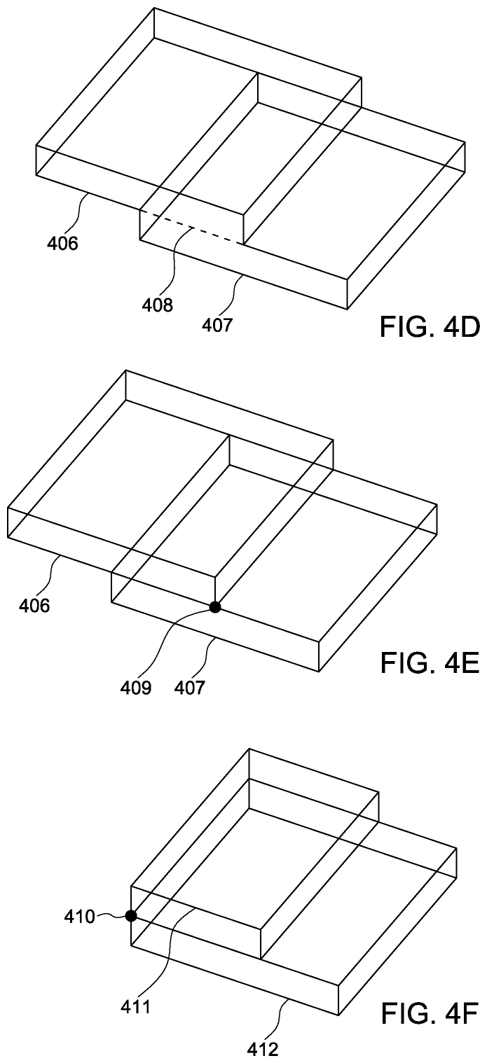

Referring now to FIGS. 4A-4F, exemplary contact types for bodies are illustrated, in accordance with some embodiments of the present invention. FIGS. 4A-4F are explained in conjunction with FIGS. 1-3. The contact types may be classified based on entities which are in contact. The entities considered for contact identification may include a face, an edge, and a vertex. In FIG. 4A, a face-face contact type is illustrated. It may be noted that a bottom face of the body 401 is touching a top face of the body 402. Thus, a contact between the body 401 and the body 402 may be a face-face contact 403 and a type of contact may be the face-face contact type.

In FIG. 4B, a face-edge contact type is illustrated. It may be noted that an edge of the body 401 is touching the top face of the second body 402. Thus, the contact between the body 401 and the body 402 may be a face-edge contact 404, and the type of contact may be the face-edge contact type.

In FIG. 4C, a face-vertex contact type is illustrated. It may be noted that a vertex of the body 401 is touching the top face of the body 402. Therefore, the contact between the body 401 and the body 402 may be a face-vertex contact 405, and the type of contact may be the face-vertex contact type.

Referring to FIG. 4D, an edge-edge contact type is illustrated. It may be noted that the edge of the body 406 is touching the edge of the body 407. Thus, the contact between the body 406 and the body 407 may be an edge-edge contact 408, and the contact type may be the edge-edge contact type. In FIG. 4E, an edge-vertex contact type is illustrated. It may be noted that the vertex of the body 406 is touching the edge of the body 407. Therefore, the contact between the body 406 and the body 407 may be an edge-vertex contact 409, and the contact type may be the edge-vertex contact type.

Referring to FIG. 4F, a vertex-vertex contact type is illustrated. It may be noted that the vertex of a body 411 is touching the vertex of a body 412. Thus, the contact may be a vertex-vertex contact 410, and the contact type may be the vertex-vertex contact type.

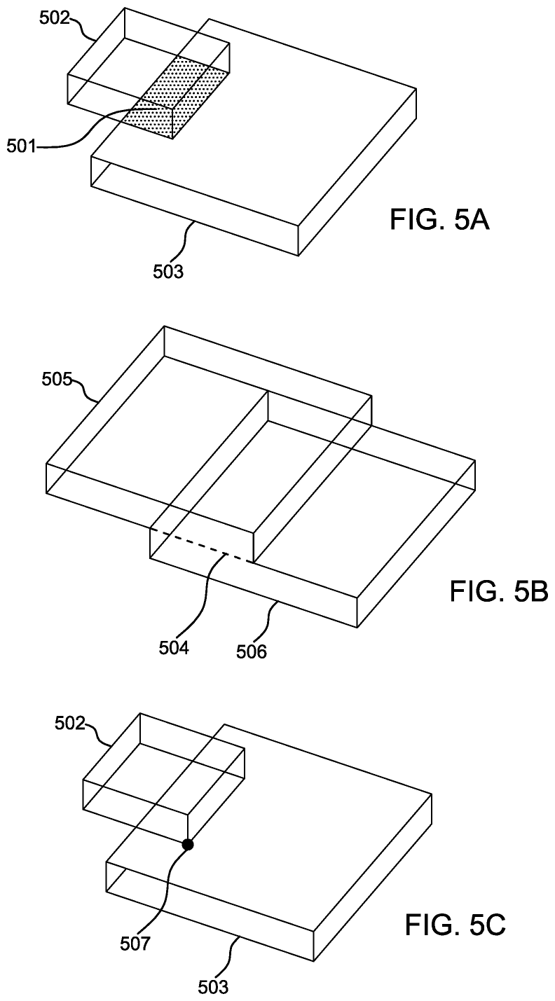

Referring now to FIGS. 5A-5C, contact regions for different contact types of the bodies are illustrated, in accordance with some embodiments of the present invention. FIGS. 5A-5C are explained in conjunction with FIGS. 1-4. A contact region may be an actual overlap portion of the contact between the entities. FIG. 5A illustrates a 2D contact region 501. It should be noted that a face-face contact always corresponds to a 2D contact region. For example, the 2D contact region 501 may be for the face-face contact (for example the face-face contact 403) of bodies 502 and 503.

FIG. 5B illustrates a 1D contact region 504. It should be noted that a face-edge contact and an edge-edge contact always correspond to a 1D contact region. For example, the 1D contact region 504 may be for the edge-edge contact (for example the edge-edge contact 408) of bodies 505 and 506. FIG. 5C illustrates a 0D contact region 507. It should be noted that a face-vertex contact, an edge-vertex contact, and a vertex-vertex contact always correspond to a 0D contact region. For example, the 0D contact region 507 may be for the face-vertex contact (for example the face-vertex contact 405) of the bodies 502 and 503.

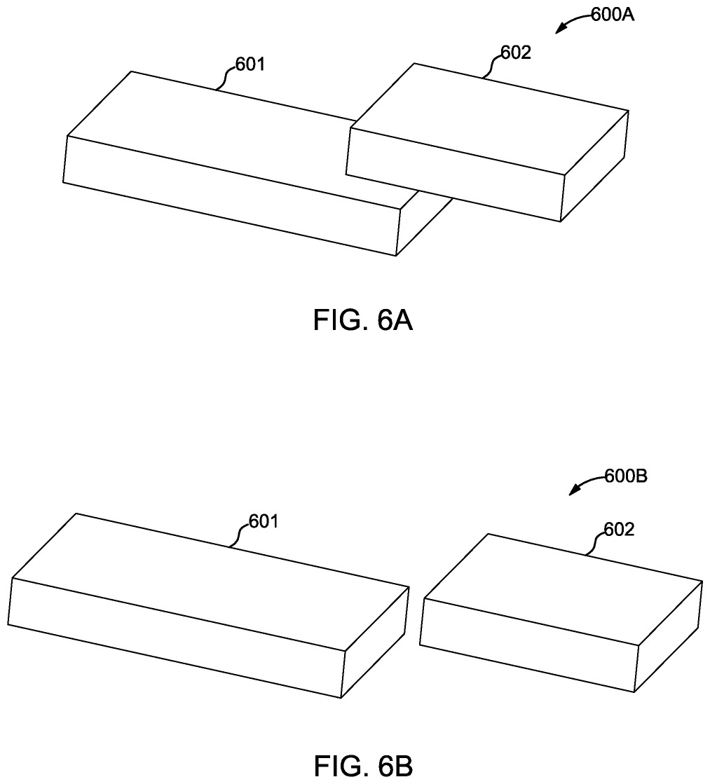

Referring now to FIGS. 6A-6B, exemplary scenarios while identifying associated body pairs are illustrated, in accordance with some embodiments of the present invention. FIGS. 6A-6B are explained in conjunction with FIGS. 1-5. FIG. 6A illustrates an exemplary scenario 600A. The scenario 600A includes a body 601 and a body 602. The body 601 and the body 602 may be an associated body pair as boundary envelopes of the bodies 601 and 602 are touching/overlapping and proximity between the bodies 601 and 602 is within a predefined threshold proximity. Thus, the scenario 600A may be a valid scenario for finding the contacts between the bodies 601 and 602. Further, FIG. 6B illustrates a scenario 600B. In the scenario 600B, the bodies 601 and 602 may not be considered as the associated body pair as the boundary envelopes of the bodies 601 and 602 are non-touching/non-overlapping and proximity between the bodies 601 and 602 is out of a predefined threshold proximity. Thus, the scenario 600B may be an Invalid scenario for finding the contacts between the bodies 601 and 602.

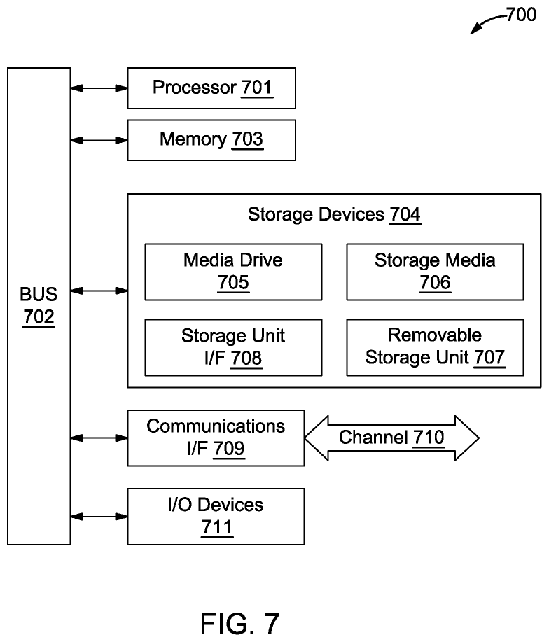

The disclosed methods and systems may be implemented on a conventional or a general-purpose computer system, such as a personal computer (PC) or server computer. Referring now to FIG. 7, an exemplary computing system 700 that may be employed to implement processing functionality for various embodiments (e.g., as a SIMD device, client device, server device, one or more processors, or the like) is illustrated. Those skilled in the relevant art will also recognize how to implement the invention using other computer systems or architectures. The computing system 700 may represent, for example, a user device such as a desktop, a laptop, a mobile phone, personal entertainment device, DVR, and so on, or any other type of special or general-purpose computing device as may be desirable or appropriate for a given application or environment. The computing system 700 may include one or more processors, such as a processor 701 that may be implemented using a general or special purpose processing engine such as, for example, a microprocessor, microcontroller or other control logic. In this example, the processor 701 is connected to a bus 702 or other communication medium. In some embodiments, the processor 701 may be an Al processor, which may be implemented as a Tensor Processing Unit (TPU), or a graphical processor unit, or a custom programmable solution Field-Programmable Gate Array (FPGA).

The computing system 700 may also include a memory 703 (main memory), for example, Random Access Memory (RAM) or other dynamic memory, for storing information and instructions to be executed by the processor 701. The memory 703 also may be used for storing temporary variables or other intermediate information during execution of instructions to be executed by the processor 701. The computing system 700 may likewise include a read only memory (“ROM”) or other static storage device coupled to bus 702 for storing static information and instructions for the processor 701.

The computing system 700 may also include a storage device 704, which may include, for example, a media drives 705 and a removable storage interface. The media drive 705 may include a drive or other mechanism to support fixed or removable storage media, such as a hard disk drive, a floppy disk drive, a magnetic tape drive, an SD card port, a USB port, a micro USB, an optical disk drive, a CD or DVD drive (R or RW), or other removable or fixed media drive. A storage media 706 may include, for example, a hard disk, magnetic tape, flash drive, or other fixed or removable medium that is read by and written to by the media drive 705. As these examples illustrate, the storage media 706 may include a computer-readable storage medium having stored there in particular computer software or data.

In alternative embodiments, the storage devices 704 may include other similar instrumentalities for allowing computer programs or other instructions or data to be loaded into the computing system 700. Such instrumentalities may include, for example, a removable storage unit 707 and a storage unit interface 708, such as a program cartridge and cartridge interface, a removable memory (for example, a flash memory or other removable memory module) and memory slot, and other removable storage units and interfaces that allow software and data to be transferred from the removable storage unit 707 to the computing system 700.

The computing system 700 may also include a communications interface 709. The communications interface 709 may be used to allow software and data to be transferred between the computing system 700 and external devices. Examples of the communications interface 709 may include a network interface (such as an Ethernet or other NIC card), a communications port (such as for example, a USB port, a micro USB port), Near field Communication (NFC), etc. Software and data transferred via the communications interface 709 are in the form of signals which may be electronic, electromagnetic, optical, or other signals capable of being received by the communications interface 709. These signals are provided to the communications interface 709 via a channel 710. The channel 710 may carry signals and may be implemented using a wireless medium, wire or cable, fiber optics, or other communications medium. Some examples of the channel 710 may include a phone line, a cellular phone link, an RF link, a Bluetooth link, a network interface, a local or wide area network, and other communications channels.

The computing system 700 may further include Input/Output (I/O) devices 711. Examples may include, but are not limited to a display, keypad, microphone, audio speakers, vibrating motor, LED lights, etc. The I/O devices 711 may receive input from a user and also display an output of the computation performed by the processor 701. In this document, the terms “computer program product” and “computer-readable medium” may be used generally to refer to media such as, for example, the memory 703, the storage devices 704, the removable storage unit 707, or signal(s) on the channel 710. These and other forms of computer-readable media may be involved in providing one or more sequences of one or more instructions to the processor 701 for execution. Such instructions, generally referred to as “computer program code” (which may be grouped in the form of computer programs or other groupings), when executed, enable the computing system 700 to perform features or functions of embodiments of the present invention.

In an embodiment where the elements are implemented using software, the software may be stored in a computer-readable medium and loaded into the computing system 700 using, for example, the removable storage unit 707, the media drive 705 or the communications interface 709. The control logic (in this example, software instructions or computer program code), when executed by the processor 701, causes the processor 701 to perform the functions of the invention as described herein.

Thus, the present disclosure may overcome drawbacks of traditional systems discussed before. The present disclosure can be used in the manufacturing domain. For example, identified contact features may be utilized for various applications including selecting the most suitable joining method based on the contact type, determining welding time and cost, automation of welding path, and the like. The disclosure further helps in reducing the uncertainty in classification by considering user control parameters contact feature identification.

It will be appreciated that, for clarity purposes, the above description has described embodiments of the invention with reference to different functional units and processors. However, it will be apparent that any suitable distribution of functionality between different functional units, processors or domains may be used without detracting from the invention. For example, functionality illustrated to be performed by separate processors or controllers may be performed by the same processor or controller. Hence, references to specific functional units are only to be seen as references to suitable means for providing the described functionality, rather than indicative of a strict logical or physical structure or organization.

Although the present invention has been described in connection with some embodiments, it is not intended to be limited to the specific form set forth herein. Rather, the scope of the present invention is limited only by the claims. Additionally, although a feature may appear to be described in connection with particular embodiments, one skilled in the art would recognize that various features of the described embodiments may be combined in accordance with the invention.

Furthermore, although individually listed, a plurality of means, elements or process steps may be implemented by, for example, a single unit or processor. Additionally, although individual features may be included in different claims, these may possibly be advantageously combined, and the inclusion in different claims does not imply that a combination of features is not feasible and/or advantageous. Also, the inclusion of a feature in one category of claims does not imply a limitation to this category, but rather the feature may be equally applicable to other claim categories, as appropriate.

What is claimed is:

1. A method for identifying contact features of Boundary Representation (B-Rep)-based Computer Aided Design (CAD) models, the method comprising:
for each body of a plurality of bodies, determining, by a feature identification device, a body type associated with the body from a plurality of body types based on information extracted from a boundary representation of the body, wherein each of the plurality of bodies is a B-Rep-based CAD model, and wherein each of the plurality of body types is one of an invalid body type and a valid body type;
identifying, by the feature identification device, one or more associated body pairs from a set of valid bodies based on a proximity between each two of the set of valid bodies and a predefined threshold proximity, wherein the body type of each of the set of valid bodies is the valid body type;
for each of the one or more associated body pairs, identifying, by the feature identification device, one or more face pairs for each body of the one or more associated body pairs based on a single-body criteria, and for each pair of the one or more associated body pairs based on a multi-body criteria; and
identifying, by the feature identification device, a set of contact features comprising contact parameters from each of the one or more face pairs based on a plurality of user control parameters.

2. The method of claim 1, wherein the invalid body type is one of a non-manifold body type, a multi-part body type, a surface body type, or a wire body type.

3. The method of claim 1, wherein identifying the one or more associated body pairs comprises:
receiving the set of valid bodies;
for each two bodies of the set of valid bodies,
calculating the proximity between boundary envelopes of the two bodies; and, one of:
establishing the two bodies as an associated body pair when the proximity is within the predefined threshold proximity; or
establishing the two bodies as a non-contacting body pair when the proximity is not within the predefined threshold proximity.

4. The method of claim 1, wherein identifying one or more face pairs based on the single-body criteria comprises, for each body of each of the one or more associated body pairs, determining if the proximity between two faces of the body is within the predefined threshold proximity.

5. The method of claim 1, wherein identifying one or more face pairs based on the multi-body criteria comprises, for each body pair of the one or more associated body pairs, determining if the proximity between a face of each of the body pair is within the predefined threshold proximity.

6. The method of claim 1, wherein the contact parameters comprise one or more contact types, one or more contact entities, and one or more contact regions.

7. The method of claim 6, wherein the one or more contact types comprise at least one of a face-face contact type, a face-vertex contact type, a face-edge contact type, an edge-edge contact type, an edge-vertex contact type, and a vertex-vertex contact type, and wherein the one or more contact regions comprise a two-dimensional (2D) contact region, a one-dimensional (1D) contact region, and a zero-dimensional (0D) contact region

8. The method of claim 6, further comprising validating each of the one or more contact types based on the corresponding one or more contact regions, wherein:
the face-face contact type corresponds to the 2D contact region;
each of the face-edge contact type and the edge-edge contact type corresponds to the 1D contact region; and
each of the face-vertex contact type, the edge-vertex contact type, and the vertex-vertex contact type corresponds to the 0D contact region.

9. A system for identifying contact features of Boundary Representation (B-Rep)-based Computer Aided Design (CAD) models, the system comprising:
a processor; and
a memory communicatively coupled to the processor, wherein the memory stores processor-executable instructions, which, on execution, cause the processor to:
for each body of a plurality of bodies, determine a body type associated with the body from a plurality of body types based on information extracted from a boundary representation of the body, wherein each of the plurality of bodies is a B-Rep-based CAD model, and wherein each of the plurality of body types is one of an invalid body type and a valid body type;
identify one or more associated body pairs from a set of valid bodies based on a proximity between each two of the set of valid bodies and a predefined threshold proximity, wherein the body type of each of the set of valid bodies is the valid body type;
for each of the one or more associated body pairs, identify one or more face pairs for each body of the one or more associated body pairs based on a single-body criteria, and for each pair of the one or more associated body pairs based on a multi-body criteria; and
identify a set of contact features and corresponding contact parameters from each of the one or more face pairs based on a plurality of user control parameters.

10. The system of claim 9, wherein the invalid body type is one of a non-manifold body type, a multi-part body type, a surface body type, or a wire body type.

11. The system of claim 9, wherein the processor-executable instructions further cause the processor to identify the one or more associated body pairs by:
receiving the set of valid bodies;
for each two bodies of the set of valid bodies,
calculating the proximity between boundary envelopes of the two bodies; and, one of:
establishing the two bodies as an associated body pair when the proximity is within the predefined threshold proximity; or
establishing the two bodies as a non-contacting body pair when the proximity is out of the predefined threshold proximity.

12. The system of claim 9, wherein the processor-executable instructions further cause the processor to identify one or more face pairs based on the single-body criteria, for each body of each of the one or more associated body pairs, by determining if the proximity between two faces of the body is within the predefined threshold proximity.

13. The system of claim 9, wherein the processor-executable instructions further cause the processor to identify one or more face pairs based on the multi-body criteria, for each body pair of the one or more associated body pairs, by determining if the proximity between a face of each of the body pair is within the predefined threshold proximity.

14. The system of claim 9, wherein the contact parameters comprise one or more contact types, one or more contact entities, and one or more contact regions

15. The system of claim 14, wherein the one or more contact types comprise at least one of a face-face contact type, a face-vertex contact type, a face-edge contact type, an edge-edge contact type, and a vertex-vertex contact type, and wherein the one or more contact regions comprise a two-dimensional (2D) contact region, a one-dimensional (1D) contact region, and a zero-dimensional (0D) contact region.

16. The system of claim 14, wherein the processor-executable instructions further cause the processor to validate each of the one or more contact types based on the corresponding one or more contact regions, wherein:
the face-face contact type corresponds to the 2D contact region;
each of the face-edge contact type and the edge-edge contact type corresponds to the 1D contact region; and
each of the face-vertex contact type, the edge-vertex contact type, and the vertex-vertex contact type corresponds to the 0D contact region.

17. A non-transitory computer-readable medium storing computer-executable instructions for identifying contact features of Boundary Representation (B-Rep)-based Computer Aided Design (CAD) models, the computer-executable instructions configured for:
for each body of a plurality of bodies, determining a body type associated with the body from a plurality of body types based on information extracted from a boundary representation of the body, wherein each of the plurality of bodies is a B-Rep-based CAD model, and wherein each of the plurality of body types is one of an invalid body type and a valid body type;
identifying one or more associated body pairs from a set of valid bodies based on a proximity between each two of the set of valid bodies and a predefined threshold proximity, wherein the body type of each of the set of valid bodies is the valid body type;
for each of the one or more associated body pairs, identifying one or more face pairs for each body of the one or more associated body pairs based on a single-body criteria, and for each pair of the one or more associated body pairs based on a multi-body criteria; and
identifying a set of contact features and corresponding contact parameters from each of the one or more face pairs based on a plurality of user control parameters.

18. The non-transitory computer-readable medium of the claim 17, wherein the computer-executable instructions further configured for identifying the one or more associated body pairs by:
receiving the set of valid bodies;
for each two bodies of the set of valid bodies,
calculating the proximity between boundary envelopes of the two bodies; and, one of:
establishing the two bodies as an associated body pair when the proximity is within the predefined threshold proximity; or
establishing the two bodies as a non-contacting body pair when the proximity is not within the predefined threshold proximity.

19. The non-transitory computer-readable medium of the claim 17, wherein the computer-executable instructions further configured for identifying one or more face pairs based on the single-body criteria by determining if the proximity between two faces of the body is within the predefined threshold proximity.

20. The non-transitory computer-readable medium of the claim 17, wherein the computer-executable instructions further configured for identifying one or more face pairs based on the multi-body criteria by determining if the proximity between a face of each of the body pair is within the predefined threshold proximity for each body pair of the one or more associated body pairs.
